(19) United States
(12) Patent Application Publication
(10) Pub. No.: US 2006/0177074 A1
(43) Pub. Date: Aug. 10, 2006

(54) Early reflection reproduction apparatus and method of sound field effect reproduction

(76) Inventor: Byeong-seob Ko, Suwon-si (KR)

Correspondence Address: STANZIONE & KIM, LLP, 919 18TH STREET, N.W., SUITE 440, WASHINGTON, DC, 20006, US

(21) Appl. No.: 11/280,270

(22) Filed: Nov. 17, 2005

(30) Foreign Application Priority Data
Feb. 5, 2005 (KR) 2005-11015

(51) Int. Cl. H03G 3/00; G10H 1/02

(52) U.S. Cl. 381/63; 84/630

(57) ABSTRACT

An early reflection reproducing method and apparatus to reproduce sound field effect. The method includes generating a plurality of early reflections having principal reflection components by considering measured spatial impulse response characteristics of a predetermined sound field, and generating residual reflections of the principal reflection components and adding the generated residual reflections to the principal reflection components of the plurality of early reflections. Thus, by generating the residual reflections after FIR filtering, presence and ambience can be improved and an amount of processing and memory used to reproduce the sound field effect can be minimized.

### CROSS-REFERENCE TO RELATED APPLICATIONS

This application claims priority from Korean Patent Application No. 2005-11015, filed on Feb. 5, 2005, in the Korean Intellectual Property Office, the disclosure of which is incorporated herein in its entirety by reference.

### BACKGROUND OF THE INVENTION

1. Field of the Invention

The present general inventive concept relates to a sound field effect reproducing system usable with a television, a portable media player, etc., and more particularly, to an early reflection reproducing apparatus and method of sound field effect reproduction.

2. Description of the Related Art

Generally, sounds that are heard in a concert hall include direct sounds and indirect sounds due to complicated reflections from, for example, surrounding walls of the concert hall. The indirect sounds that correspond to the reflections reinforce the direct sounds, since reflected sounds that reach a listener within 50 ms (80 ms for music sounds) following the direct sounds are heard as a single sound in combination with the direct sounds.

When the direct sounds are weak, energy of the direct sounds should be increased using early reflections. Early reflections are reflections that occur a relatively short time after the direct sounds are heard. A recent discovery indicates that lateral reflections influence a spatial impression that corresponds to a feeling of being enveloped by sound.

The early reflections result from a time delay and phase difference between sound signals received by left and right ears.

Therefore, when reproducing music through a sound reproducing apparatus, such as a stereo, early reflected sounds can be artificially produced and added to an original sound, producing the effect of sound heard in, for example, a concert hall.

A conventional early reflection reproducing apparatus uses a digital filter which considers complex reflection patterns of the early reflections to be of a single impulse component. Therefore, the conventional early reflection reproducing apparatus requires numerous impulse coefficients that correspond to the early reflections in order to achieve good presence and ambience. As a result, the conventional early reflection reproducing apparatus requires a large amount of processing and memory load.

### SUMMARY OF THE INVENTION

The present general inventive concept provides an early reflection reproducing method and apparatus which achieves good presence and ambience while requiring minimum processing calculations and memory by generating and adding residual reflections to each principal reflection component of early reflections after finite impulse response (FIR) filtering is performed.

The present general inventive concept also provides a sound field effect reproducing system employing the early reflection reproducing apparatus and/or method.

Additional aspects of the present general inventive concept will be set forth in part in the description which follows and, in part, will be obvious from the description, or may be learned by practice of the general inventive concept.

The foregoing and/or other aspects of the present general inventive concept may be achieved by providing an early reflection reproducing method, including generating a plurality of early reflections including principal reflection components by considering measured spatial impulse response characteristics of a predetermined sound field, and generating residual reflections of the principal reflection components and adding the residual reflections to the respective principal reflection components of the plurality of early reflections.

The foregoing and/or other aspects of the present general inventive concept are also achieved by providing a method of reproducing a sound field effect of a predetermined sound field, the method comprising receiving an input signal, determining principal reflection components of early reflections of the received input signal according to a predetermined principal reflection impulse pattern of the predetermined sound field, deriving residual reflection components of the determined principal reflection components according to a magnitude and position of the determined principal reflection components, and adding the derived residual reflection components to the determined principal reflection components, and outputting an output signal having the input signal, the determined principal reflection components, and the derived residual reflection components.

The foregoing and/or other aspects of the present general inventive concept are also achieved by providing a sound field effect reproducing method, the method comprising applying a stored principal reflection impulse pattern to an input signal to determine principal reflections thereof in a predetermined sound field, determining residual reflections of the input signal in the predetermined sound field from the principal reflections, and combining the input signal with the principal and residual reflections.

The foregoing and/or other aspects of the present general inventive concept may also be achieved by providing a sound field effect reproducing system, including a low-pass filter unit to reduce high frequency band components of an input signal, an early reflection generating unit to generate early reflections of the filtered input signal including principal reflection components based on spatial impulse response characteristic coefficients, a residual reflection generating unit to continuously generate residual reflections of the principal reflection components of the plurality of early reflections generated by the early reflection generating unit, and an adding unit to add the input signal to the early reflections generated by the early reflection generating unit.

The foregoing and/or other aspects of the present general inventive concept are also achieved by providing a sound field effect reproducing system, comprising a memory unit to store a principal reflection impulse pattern of a predetermined sound field, an early reflection generating unit to apply the stored principal reflection impulse pattern to an input signal to determine principal reflections thereof in the predetermined sound field, a residual reflection generating unit to determine residual reflections of the input signal in the predetermined sound field from the principal reflections, and a combination unit to combine the input signal with the principal and residual reflections.

The foregoing and/or other aspects of the present general inventive concept are also achieved by providing a computer readable medium containing executable code to perform a sound field effect reproducing method, the medium comprising a first executable code to apply a stored principal reflection impulse pattern to an input signal to determine principal reflections thereof in a predetermined sound field, a second executable code to determine residual reflections of the input signal in the predetermined sound field from the principal reflections, and a third executable code to combine the input signal with the principal and residual reflections.

### BRIEF DESCRIPTION OF THE DRAWINGS

These and/or other aspects of the present general inventive concept will become apparent and more readily appreciated from the following description of the embodiments, taken in conjunction with the accompanying drawings of which:

FIG. 1 is a block diagram illustrating a sound field effect reproducing system according to an embodiment of the present general inventive concept;

FIGS. 2A through 2C are views illustrating an impulse response measured by a spatial impulse response measuring unit of the sound field effect reproducing system of FIG. 1 according to an embodiment of the present general inventive concept;

FIG. 3A is a view illustrating a decimated impulse response produced by the spatial impulse response measuring unit of the sound field effect reproducing system of FIG. 1 according to an embodiment of the present general inventive concept;

FIG. 3B is a block diagram illustrating an early reflection generating unit of the sound field effect reproducing system of FIG. 1;

FIG. 4 illustrates a result of an impulse pattern of the impulse response of FIGS. 2A through 2C;

FIG. 5A is a block diagram illustrating a residual reflection generating unit of the sound field effect reproducing system of FIG. 1 according to an embodiment of the present general inventive concept; and

FIG. 5B illustrates output characteristics generated by the residual reflection generating unit of FIG. 5A.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures.

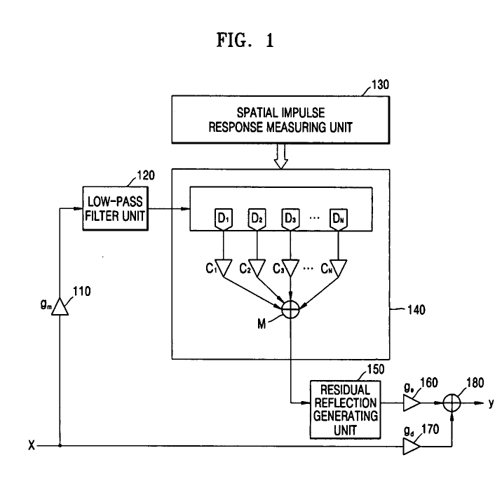

FIG. 1 is a block diagram illustrating a sound field effect reproducing system according to an embodiment of the present general inventive concept.

The sound field effect reproducing system includes a low-pass filter unit 120, a spatial impulse response measuring unit 130, an early reflection generating unit 140, a residual reflection generating unit 150, an adding unit 180, an input level adjusting unit 110, a first output level adjusting unit 160, and a second output level adjusting unit 170.

The spatial impulse response measuring unit 130 generates finite impulse response (FIR) filter coefficients c₁, c₂, c₃, . . . , and cₙ and FIR filter delay values d₁, d₂, d₃, . . . , and dₙ, to be used in the early reflection generating unit 140 based on impulse responses measured in a predetermined sound field or room. The predetermined sound field or room may be, for example, a concert hall, auditorium, studio, etc.

The input level adjusting unit 110 reduces an input signal x by an adjusted gain coefficient gₘ.

The low-pass filter unit 120 performs low-pass filtering of the input signal x adjusted by the input level adjusting unit 110, to reduce high frequency band components in the input signal x.

The early reflection generating unit 140 includes an FIR filter which generates early reflections using the FIR filter coefficients c₁, c₂, c₃, . . . , and cₙ and the FIR filter delay values d₁, d₂, d₃, . . . , and dₙ generated by the spatial impulse response measuring unit 130. Additionally, the early reflection generating unit 140 adds the generated early reflections to the input signal x that is filtered by the low-pass filter unit 120, thereby creating an early reflection signal.

The residual reflection generating unit 150 generates residual reflections of each principal reflection component of the early reflections generated by the early reflection generating unit 140, adds the generated residual reflections to each principal reflection component of the early reflections, and outputs the early reflection signal having residual reflections thereof added thereto. For example, the residual reflection generating unit 150 may use an all-pass filter which combines a delay circuit, an adder, and a multiplier.

The first output level adjusting unit 160 adjusts a level of the early reflection signal output from the residual reflection generating unit 150 by an adjusted gain coefficient gₑ.

The second output level adjusting unit 170 adjusts the level of an original input signal x by an adjusted gain coefficient g_{d}.

The adding unit 180 adds the adjusted early reflection signal output from the first output level adjusting unit 160 to the adjusted input signal x output from the second output level adjusting unit 170 to generate a final output signal y having a sound field effect that corresponds to the predetermined sound field or room.

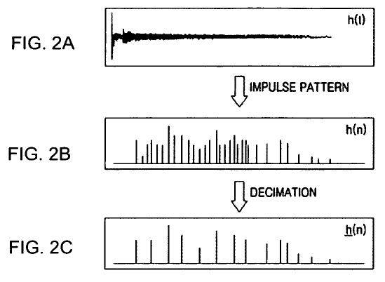

FIGS. 2A through 2C are views illustrating an impulse response measured by the spatial impulse response measuring unit 130 of the sound field effect reproducing system illustrated in FIG. 1 according to an embodiment of the present general inventive concept.

An impulse response h(t) as illustrated in FIG. 2A is measured in the predetermined sound field or room, for example, a concert hall. The impulse response h(t) may be measured in various other sound fields to produce a desired sound field effect.

The measured impulse response h(t) is then made into an impulse pattern h(n) as illustrated in FIG. 2B. For example, the impulse response pattern h(n) may be derived from the measured impulse response h(t) by sampling at a predetermined sample period T.

The impulse response pattern h(n) is then decimated into an impulse pattern h(n) as illustrated in FIG. 2C to simplify calculation. This decimation may be performed by removing certain data from the impulse response pattern h(n). For example, certain sample points may be discarded. Multiple filter coefficients c and filter delay values d between impulses are extracted from impulse response characteristics, in which only main components are extracted by decimation, to generate the early reflections. That is, the filter coefficients c and the filter delay values d may be selected to correspond to impulses of the impulse pattern h(n). The filter coefficients c and the filter delay values d may then be used by the early reflection generating unit 140 to generate principal components of the early reflections accordingly. Although the spatial impulse response measuring unit 130 is illustrated as part of the sound field effect reproducing system in FIG. 1, it should be understood that the impulse response h(t) may be measured before operation of the sound field effect reproducing system. Additionally, the filter coefficients c and the filter delay values d that are derived from the measured impulse response h(t) may be pre-stored in a memory unit before operation of the sound field effect reproducing system. In this case, the spatial impulse response measuring unit 130 may not be necessary during operation of the early reflection generating unit 140, and the early reflection generating unit 140 can access the memory unit to retrieve the filter coefficients c and filter delay values d that are pre-stored to create the early reflections. Alternatively, the memory unit may store the impulse pattern h(n) such that h(n) may be applied by the early reflection generating unit 140 to each input signal.

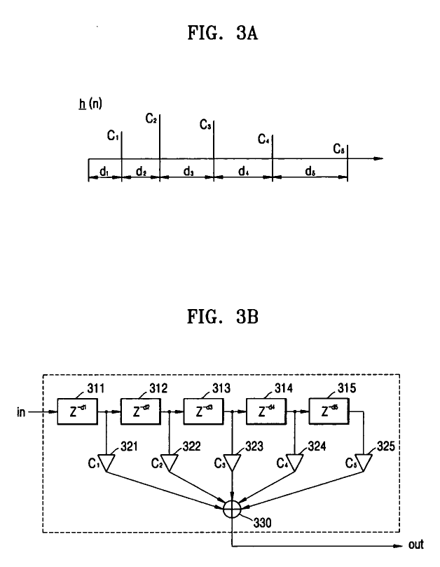

FIG. 3A is a view illustrating the decimated impulse pattern h(n) of the impulse response measured by the spatial impulse response measuring unit 130 illustrated in FIG. 1 according to an embodiment of the present general inventive concept.

Referring to FIG. 3A, the spatial impulse response measuring unit 130 extracts multiplying coefficients c₁ through c₅ of each impulse of the decimated impulse pattern h(n) and delay values d₁ through d₅ between the impulses that correspond to FIR filter coefficients (i.e., the multiplying coefficients c₁ through c₅) and the delay values d₁ through d₅ from the decimated impulse pattern to generate the early reflections.

FIG. 3B is a block diagram illustrating the early reflection generating unit 140 of the sound field effect reproducing system of FIG. 1.

Five delay circuits 311, 312, 313, 314, and 315 having delay times d1, d2, d3, d4, and d5, respectively, are connected in a series. The early reflection generating unit 140 is arranged to pass respective outputs from the delay circuits 311, 312, 313, 314, and 315 through multipliers 321, 322, 323, 324, and 325 having the multiplying coefficients c₁ through c₅, respectively, and then provide the results to an adder 330. A circuit including the delay circuits 311, 312, 313, 314, and 315, the multipliers 321, 322, 323, 324, and 325, and the adder 330 may be a FIR filter.

Referring to FIG. 3B, the FIR filter that generates the early reflections is configured based on the multiplying coefficients c₁ through c₅ and the delay values d₁ through d₅ measured in the predetermined sound field or room. For example, the predetermined sound field may be a concert hall, auditorium, studio, etc. In particular, the predetermined sound field may be any room that causes early reflections. That is, the multiplying coefficients c₁ through c₅ and the delay values d₁ through d₅ of the impulses of the impulse pattern h(n) of the impulse response h(t) measured in the predetermined sound field or room are applied respectively to the multipliers 321, 322, 323, 324, and 325 and the delay circuits 311, 312, 313, 314, and 315.

Therefore, the input signal x that is filtered by the low-pass filter 120 (see FIG. 1) is delayed by each tap of the delay circuits 311, 312, 313, 314, and 315. Portions of the delayed signal are then multiplied by the multiplying coefficients c₁ through c₅ of the multipliers 321, 322, 323, 324, and 325, respectively, that represent the impulse pattern h(n) of the early reflections as coefficients to generate early reflections. The portions of the delayed signal that are multiplied by the multipliers 321, 322, 323, 324, and 325 are then added together by the adder 330.

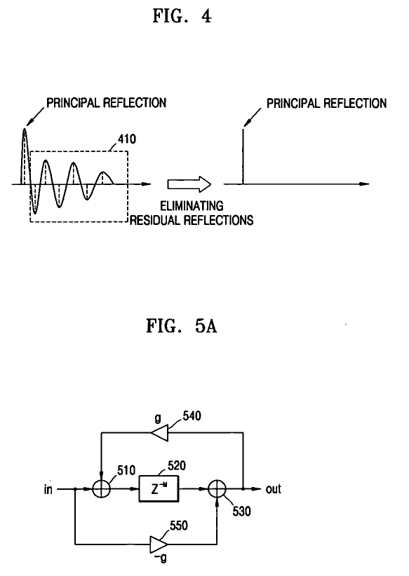

FIG. 4 illustrates a result of the impulse pattern h(n) of the measured impulse response h(t) illustrated in FIGS. 2A through 2C.

Referring to FIG. 4, residual reflections 410 which continuously exist with the principal reflection component are eliminated when the impulse response h(t) measured in the predetermined sound field or the room (e.g., the concert hall) is patterned into an impulse stream that corresponds to the impulse pattern h(n). Therefore, the measured impulse response h(t) that is converted into the impulse pattern h(n) may be converted into a single impulse in which only the principal reflection component exists, without the residual reflections 410. Consequently, the early reflection generating unit of FIG. 3B generates impulse pattern components containing no residual reflections 410, thereby reducing presence and ambience. Since the residual reflections 410 are removed, less memory and processing is required to process the impulse pattern h(n).

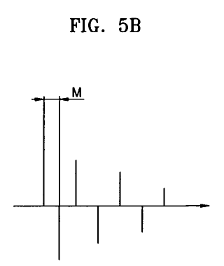

FIGS. 5A and 5B are views illustrating the residual reflection generating unit 150 of the sound field effect reproducing system of FIG. 1 according to an embodiment of the present general inventive concept.

In the residual reflection generating unit illustrated in FIG. 5A, adders 510 and 530 are connected to input and output ports of a delay circuit 520 having a delay time M. The residual reflection generating unit 150 is arranged to feed-forward an input signal “in” to the adder 530 through a multiplier 550 having a gain reducing coefficient −g, and to feed-back an output signal “out” of the adder 530 to the adder 510 through a multiplier 540 having a gain increasing coefficient g.

A circuit including the delay circuit 520, the adders 510 and 530, and the multipliers 540 and 550 may be an all-pass filter, and characteristics of the output signal “out” are illustrated in FIG. 5B. It should be noted that the delay time M is exaggerated in FIG. 5B for illustration purposes. Impulse response signals of all bands having the delay time M as illustrated in FIG. 5B are added to each principal reflection component of the early reflections as the residual reflections. The delay time M may be selected such that residual reflections occurring M, 2M, 3M, etc. from the principal reflection component may be added thereto. The gain reducing coefficient −g and the gain increasing coefficient g may be selected such that the residual reflections occurring M, 2M, 3M, etc, from the principal reflection component gradually decrease in magnitude to create an attenuation effect.

Consequently, the residual reflections, which are previously removed by signals of the impulse pattern h(n), are re-generated and added to the principal reflection component of the early reflections using the residual reflection generating unit of FIG. 5A, which may include the all-pass filter. In other words, by processing the principal reflection components and subsequently deriving the residual reflections therefrom, minimal memory and processing is required by the system. For example, the impulse pattern h(n) (i.e., the decimated impulse pattern h(n)) may be stored and processed rather than the impulse response pattern h(n), which includes data for the residual reflections. The residual reflections may be derived from the principal reflection components in the impulse pattern h(n), after an input signal is processed with the impulse pattern h(n). Thus, the presence and ambience gained by adding the residual reflections to the principal reflection components can be achieved without a significant increase in memory or processing.

The embodiments of the present general inventive concept can be embodied as computer readable codes on a computer readable recording medium. The computer readable recording medium may include any data storage device that can store data which can be thereafter read by a computer system. Examples of the computer readable recording medium include a read-only memory (ROM), a random-access memory (RAM), CD-ROMs, magnetic tapes, floppy disks, optical data storage devices, and carrier waves (such as data transmission through the Internet). The computer readable recording medium can also be distributed over network coupled computer systems so that the computer readable code is stored and executed in a distributed fashion. The embodiments of the present general inventive concept may also be embodied in hardware or a combination of hardware and software.

As described above, the various embodiments of the present general inventive concept can increase a presence and an ambience using a minimal amount of processing (e.g., number of operations) and memory. For example, the various embodiments of the present general inventive concept may employ an amount of processing and memory that is similar to a conventional early reflection reproducing method while considering both principal reflection components and residual reflections, unlike the conventional reproducing method, which considers a single impulse. When a sound field effect system is implemented in a low capacity system, a problem associated with a possible reduction of a capability of the sound field effect system due to limitations of memory and processing load can be overcome by the present general inventive concept. Accordingly, a sound effect of a predetermined sound field or room can be reproduced by the system of the present general inventive concept using minimal resources (i.e., memory and processing load).

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. An early reflection reproducing method, the method comprising:
generating a plurality of early reflections including principal reflection components according to measured spatial impulse response characteristics of a predetermined sound field; and
generating residual reflections of the principal reflection components and adding the generated residual reflections to the respective principal reflection components of the plurality of early reflections.

2. The method of claim 1, wherein the generating of the plurality of early reflections comprises:
delaying an input signal through a plurality of delay elements to produce a plurality of portions of the delayed input signal;
multiplying the plurality of portions of the delayed signal by multiplying coefficients having impulse patterns that correspond to the principal reflection components of the plurality of early reflections; and
adding the multiplied portions of the delayed signal into a single signal.

3. The method of claim 1, wherein the generating of the residual reflections comprises all-pass filtering each of the principal reflection components of the plurality of early reflections.

4. A method of reproducing sound field effect of a predetermined sound field, the method comprising:
receiving an input signal;
determining principal reflection components of early reflections of the input signal according to a predetermined principal reflection impulse pattern of the predetermined sound field;
deriving residual reflection components of the determined principal reflection components according to a magnitude and position of the principal reflection components, and adding the derived residual reflection components to the principal reflection components; and
outputting an output signal having the input signal, the determined principal reflection components, and the derived residual reflection components.

5. The method of claim 4, further comprising:
pre-storing the predetermined principal reflection impulse pattern in a memory unit.

6. The method of claim 5, wherein the pre-storing of the predetermined principal reflection impulse pattern comprises:
measuring impulse response characteristics of sound in the predetermined sound field;
sampling the impulse response characteristics to determine an impulse response pattern; and
decimating the impulse response pattern to retain data that corresponds to the principal reflection components to obtain the predetermined principal reflection impulse response pattern.

7. A sound field effect reproducing method, the method comprising:
applying a stored principal reflection impulse pattern to an input signal to determine principal reflections thereof in a predetermined sound field;
determining residual reflections of the input signal in the predetermined sound field from the principal reflections; and
combining the input signal with the principal and residual reflections.

8. The method of claim 7, wherein the applying of the stored principal reflection impulse pattern comprises:
performing a plurality of delay operations that correspond to a plurality of principal reflections in the predetermined sound field to delay the input signal to provide impulses in the input signal where each of the principal reflections occur;
performing a plurality of multiplication operations that correspond to the plurality of principal reflections in the predetermined sound field to adjust magnitudes of the impulses of the principal reflections; and
combining the plurality of impulses having adjusted magnitudes to provide a principal early reflection signal.

9. The method of claim 7, wherein the determining of the residual reflections comprises:
receiving a principal early reflection signal having impulses indicating the principal reflections; and
performing at least one delay operation and at least one gain adjusting operation to determine residual reflection impulses at predetermined time delays from the principal reflection impulses such that a magnitude of the residual reflection impulses decrease as a distance from the principal reflection impulses increases.

10. The method of claim 7, wherein:
the applying of the stored principal reflection impulse pattern to the input signal comprises finite impulse response filtering the input signal to determine principal reflection impulses as first components of the input signal that are principally reflected in the predetermined sound field from the stored principal reflection impulse response pattern; and
the determining of the residual reflections of the input signal residual comprises all pass filtering the input signal to determine residual reflection impulses as second components of the input signal that are residually reflected in the predetermined sound field from the principal reflection impulses.

11. An early reflection reproducing apparatus, comprising:
an early reflection generating unit to generate a plurality of early reflections including principal reflection components according to spatial impulse response characteristic coefficients; and
a residual reflection generating unit to continuously generate residual reflections of the principal reflection components of the plurality of early reflections generated by the early reflection generating unit.

12. The apparatus of claim 11, wherein the early reflection generating unit comprises:
a delay circuit including a plurality of delay elements having a plurality of corresponding delay times connected in a series;
a multiplying unit to multiply signals output from the plurality of delay elements by multiplying coefficients that correspond to the spatial impulse response characteristic coefficients; and
an adding unit to add the multiplied signals.

13. The apparatus of claim 11, wherein the early reflection generating unit comprises a finite impulse response filter.

14. The apparatus of claim 11, wherein the residual reflection generating unit comprises an all-pass filter.

15. A sound field effect reproducing system, comprising:
an early reflection generating unit to generate a plurality of early reflections of an input signal including principal reflection components based on spatial impulse response characteristic coefficients;
a residual reflection generating unit to continuously generate residual reflections of the principal reflection components of the plurality of early reflections generated by the early reflection generating unit; and
an adding unit to add the input signal to the plurality of early reflections generated by the early reflection generating unit.

16. The system of claim 15, further comprising:
a low-pass filter unit to reduce high frequency band components of the input signal and to provide the input signal having the reduced high frequency bands to the early reflection generating unit.

17. A sound field effect reproducing system, comprising:
a memory unit to store a principal reflection impulse pattern of a predetermined sound field;
an early reflection generating unit to apply the stored principal reflection impulse pattern to an input signal to determine principal reflections thereof in the predetermined sound field;
a residual reflection generating unit to determine residual reflections of the input signal in the predetermined sound field from the principal reflections; and
a combination unit to combine the input signal with the determined principal and residual reflections.

18. The system of claim 17, wherein the early reflection generating unit comprises a finite impulse response filter including:
a plurality of delay units that correspond to a plurality of principal reflections in the predetermined sound field to delay the input signal to provide impulses in the input signal where each of the principal reflections occur;
a plurality of multipliers that correspond to the plurality of principal reflections in the predetermined sound field to adjust magnitudes of the impulses of the principal reflections; and
an adder to combine the plurality of impulses having adjusted magnitudes to provide a principal early reflection signal to the residual reflection generating unit.

19. The system of claim 17, wherein the residual reflection generating unit comprises an all pass filter including:
at least one delay unit and at least one gain adjusting unit to receive a principal early reflection signal having impulses at the principal reflections from the early reflection generating unit and to determine residual reflection impulses at predetermined time delays from the principal reflection impulses such that a magnitude of the residual reflection impulses decrease as a distance from the principal reflection impulses increases.

20. The system of claim 17, wherein:
the early reflection generating unit comprises a finite impulse response filter to determine principal reflection impulses as first components of the input signal that are principally reflected in the predetermined sound field from the stored impulse response pattern; and
the residual reflection generating unit comprises an all pass filter to determine residual reflection impulses as second components of the input signal that are residually reflected in the predetermined sound field from the principal reflection impulses.

21. The system of claim 17, wherein the early reflection generating unit applies a plurality of predetermined delay coefficients and a plurality of predetermined filter coefficients to the input signal according to the stored principal reflection impulse pattern.

22. The system of claim 21, wherein the plurality of predetermined delay coefficients are applied by a plurality of delay units arranged in series and the plurality of predetermined filter coefficients are applied by a plurality of gain adjusting units arranged in parallel to receive respective outputs from each of the plurality of delay units.

23. A computer readable medium containing executable code to perform a sound field effect reproducing method, the medium comprising:
a first executable code to apply a stored principal reflection impulse pattern to an input signal to determine principal reflections thereof in a predetermined sound field;
a second executable code to determine residual reflections of the input signal in the predetermined sound field from the principal reflections; and
a third executable code to combine the input signal with the principal and residual reflections.
